(19) United States
(12) Patent Application Publication
(10) Pub. No.: US 2010/0293426 A1
(43) Pub. Date: Nov. 18, 2010

(54) SYSTEMS AND METHODS FOR A PHASE LOCKED LOOP BUILT IN SELF TEST

(75) Inventor: Sachin D. Dasnurkar, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/762,985

(22) Filed: Apr. 19, 2010

Related U.S. Application Data
(60) Provisional application No. 61/177,844, filed on May 13, 2009.

(51) Int. Cl. G01R 31/3177; G06F 11/25

(52) U.S. Cl. 714/733; 714/E11.155

(57) ABSTRACT

An apparatus configured for a phase locked loop (PLL) built in self test (BIST) jitter measurement is described. The apparatus includes a phase detector. The phase detector produces a digital signal that describes a comparison between a reference signal and a feedback signal. The apparatus also includes a BIST controller. The BIST controller accumulates the digital signal with successive digital signals. The apparatus also includes a communication pin. The communication pin sends the accumulated signal to automatic test equipment (ATE) that determines whether the PLL is operating correctly based on the accumulated signal.

### CROSS-REFERENCE TO RELATED APPLICATIONS

This application is related to and claims priority from U.S. Provisional Patent Application Ser. No. 61/177,844 filed May 13, 2009, for “Systems and Methods for a Phase Locked Loop Built In Self Test,” with inventors Sachin D. Dasnurkar and Jacob A. Abraham.

### TECHNICAL FIELD

The present disclosure relates generally to electronic devices for communication systems. More specifically, the present disclosure relates to a phase locked loop built in self test.

### BACKGROUND

Electronic devices (cellular telephones, wireless modems, computers, digital music players, Global Positioning System units, Personal Digital Assistants, gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of digital circuits to support the processor and other parts of the device.

This increased complexity has led to an increased need for testing that can test digital circuits and/or digital systems. Testing may be used to verify or test various parts of devices, such as pieces of hardware, software or a combination of both.

In many cases the equipment used to test a device is a separate piece of equipment than the device being tested. Some testing that takes place is performed substantially by the test equipment. Benefits may be realized by providing improved methods and apparatus for providing built in self tests for electronic devices and/or components used in electronic devices.

### BRIEF DESCRIPTION OF THE DRAWINGS

FIG. 1 shows a system for production testing of a device under test (DUT);

FIG. 2 is a block diagram illustrating a phase locked loop (PLL) that may be used with the present systems and methods;

FIG. 3 is a flow diagram illustrating a method for formulating an alternative test solution for a DUT;

FIG. 4 is a block diagram illustrating a system for a PLL built in self test (BIST);

FIG. 5 is a block diagram illustrating a BIST controller;

FIG. 6 is a state diagram for a PLL BIST test mode;

FIG. 7 is a flow diagram illustrating a method for a phase locked loop BIST;

FIG. 7A illustrates means-plus-function blocks corresponding to the method of FIG. 7;

FIG. 8 is another flow diagram illustrating a method for a phase locked loop BIST;

FIG. 8A illustrates means-plus-function blocks corresponding to the method of FIG. 8;

FIG. 9 is a circuit diagram illustrating one configuration of a constant current source for use in the present systems and methods;

FIG. 10 is a circuit diagram illustrating one configuration of a feedback circuit for use in the present systems and methods;

FIG. 11 is a circuit diagram illustrating one configuration of a clocked comparator for use in the present systems and methods;

FIG. 12 is a graph illustrating the stabilization of a constant current source with feedback;

FIGS. 13a-13e are graphs illustrating the various waveforms over time in a DUT that is operated in test mode;

FIGS. 14a-b are circuit diagrams illustrating three transistor fault model conditions; and

FIG. 15 illustrates certain components that may be included within a wireless device.

### DETAILED DESCRIPTION

An integrated circuit for a phase locked loop (PLL) built in self test (BIST) is disclosed. The integrated circuit includes a phase detector that produces a digital signal that describes a comparison between a reference signal and a feedback signal. In another configuration, the integrated circuit may include an N-divider that provides the feedback signal to the phase detector. A voltage controlled oscillator (VCO) may be coupled to the N-divider.

A method for a phase locked loop (PLL) built in self test (BIST) is also disclosed. A digital signal is produced that describes a comparison between a reference signal and a feedback signal. The digital signal is routed to the phase detector (PFD) in the PLL. The digital signal is accumulated for the test mode duration and means are provided for the Automatic Test Equipment (ATE) to read the analog value of this accumulation. Whether the PLL is operating correctly is determined based on the accumulated signal by the ATE.

An apparatus for performing a phase locked loop (PLL) built in self test (BIST) is also disclosed. The apparatus includes a phase detector that is configured to produce a digital signal that describes a comparison between a reference signal and a feedback signal. The apparatus also includes a BIST controller that accumulates the PFD output signal during test mode instead of routing it to the charge pump, as it is routed during functional mode. The apparatus also includes a low frequency analog communication pin that provides the accumulated signal for ATE to determine whether the PLL is operating correctly based on the accumulated signal. In one configuration, the BIST scheme may also include a constant current source that drives a low pass filter without affecting the operating characteristics of the PLL. The BIST scheme may also include feedback circuitry for the constant current source that provides a ramp slope for the constant current source. The BIST scheme may also include a calibration controller that provides control signals to the constant current source for process-independence calibration. The BIST scheme may also include a hold circuit that provides a set bias voltage to the constant current source once calibration is complete. The feedback circuitry may include a clocked comparator. The BIST controller may use a low pass filter (LPF) to accumulate the PFD output digital signal. The apparatus may also include a multiplexer that connects a charge pump to the phase detector during mission mode, and connects the charge pump to the BIST controller during test mode.

Many different kinds of electronic devices may benefit from testing. Different kinds of such devices include, but are not limited to, cellular telephones, wireless modems, computers, digital music players, Global Positioning System units, Personal Digital Assistants, gaming devices, etc. One group of devices includes those that may be used with wireless communication systems. As used herein, the term “mobile station” refers to an electronic device that may be used for voice and/or data communication over a wireless communication network. Examples of mobile stations include cellular phones, handheld wireless devices, wireless modems, laptop computers, personal computers, etc. A mobile station may alternatively be referred to as an access terminal, a mobile terminal, a subscriber station, a remote station, a user terminal, a terminal, a subscriber unit, user equipment, etc.

A wireless communication network may provide communication for a number of mobile stations, each of which may be serviced by a base station. A base station may alternatively be referred to as an access point, a Node B, or some other terminology. Base stations and mobile stations may make use of integrated circuits with mixed signal circuitry. However, many different kinds of electronic devices, in addition to the wireless devices mentioned, may make use of integrated circuits with mixed signal circuitry. Production of integrated circuits may result in process variations that affect the operation of the mixed signal circuitry. Accordingly, a broad array of electronic devices may benefit from the systems and methods disclosed herein.

Phase locked loops (PLLs) are extensively used in modern System on a Chip (SoC) and communication modules for clock regeneration and timing synchronization. The typical low jitter characteristics make them attractive in frequency synthesis applications while the ease of generating frequency harmonics makes them stable clock generators. When treated as a black box with the internal complexity masked, the PLL module receives an input waveform and generates an output waveform which is an integral multiple in frequency of the input. PLLs may be mixed signal modules that may include multiple sensitive blocks internally and may need parametric testing to ensure complete specification compliance. Since a PLL may be commonly used as a clock generator, the quality of the output waveform may be especially important for the dependent blocks. This requires jitter measurement/settling time/output swing testing of the PLL, which may constitute qualitative tests, along with a simple PLL-lock testing that targets gross failures.

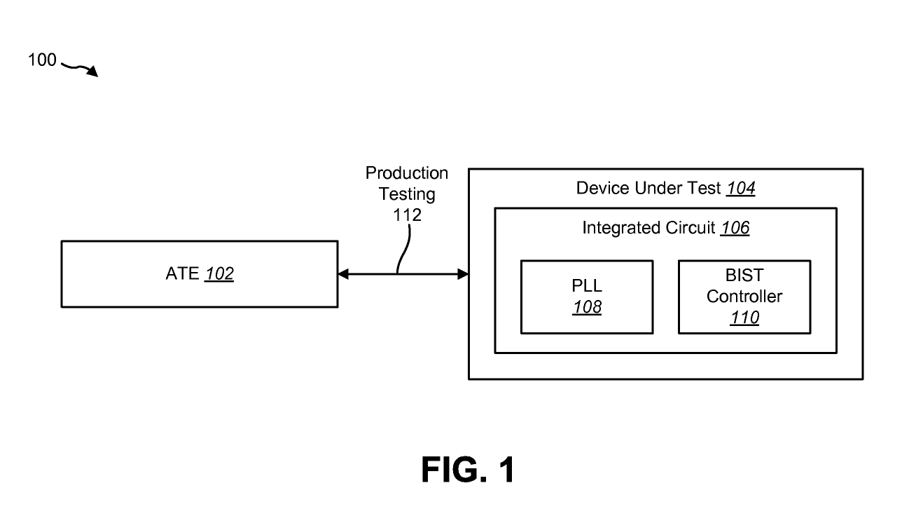

FIG. 1 is a block diagram of a system 100 for production testing 112 of a device under test (DUT) 104 with mixed signal circuitry. In one configuration, the DUT 104 may be a wireless device such as a mobile station or a base station. Alternatively, the DUT 104 may be a chip for use in a wireless device. In other configurations, the DUT 104 may not be a wireless device or part of a wireless device. The DUT 104 may include an integrated circuit 106. The integrated circuit 106 may include mixed signal circuitry. Mixed signal circuitry may be circuitry that includes both analog and digital circuitry. In one configuration, the integrated circuit 106 may include a PLL 108.

PLLs are present on a wide range of SoCs. In some cases, the PLL 108 may be the only mixed signal component present on the DUT 104. This may complicate the testing strategies because the remaining pure digital DUT 104 modules may be tested with the help of simple SCAN/at-speed/Functional tests that are digital in nature and have minimal ATE 102 hardware requirements. Such situations may be dealt with by performing a simple go-no-go frequency lock test where the PLL 108 output signal is latched by ATE 102 receive resources and the output is tested for a frequency lock achieved within a specified time duration. These tests, however, tend to be basic in nature and may not check for PLL 108 output phase, jitter, and other performance specifications, depending on ATE 102 resources available. Almost all such tests do not perform specification checks for PLL 108 output jitter (period or amplitude) or any process variations that may be compensated in the feedback loop and may cause reliability concerns in field use.

The two factors mentioned above, common use and limited structural testability, emphasize the need to provide built-in testability to enable quality production testing. The mixed signal nature of many PLL 108 sub-blocks, however, may make such BIST arrangements complicated.

A digital ATE 102 may enable full production-quality testing 112 of integrated circuits 106 that include PLLs 108 by using a BIST scheme. One way of utilizing low cost ATE 102 such as digital ATE 102 to test mixed signal integrated circuits 106 is with an on-chip BIST Controller 110. The BIST controller 110 may generate an input or signal for testing purposes.

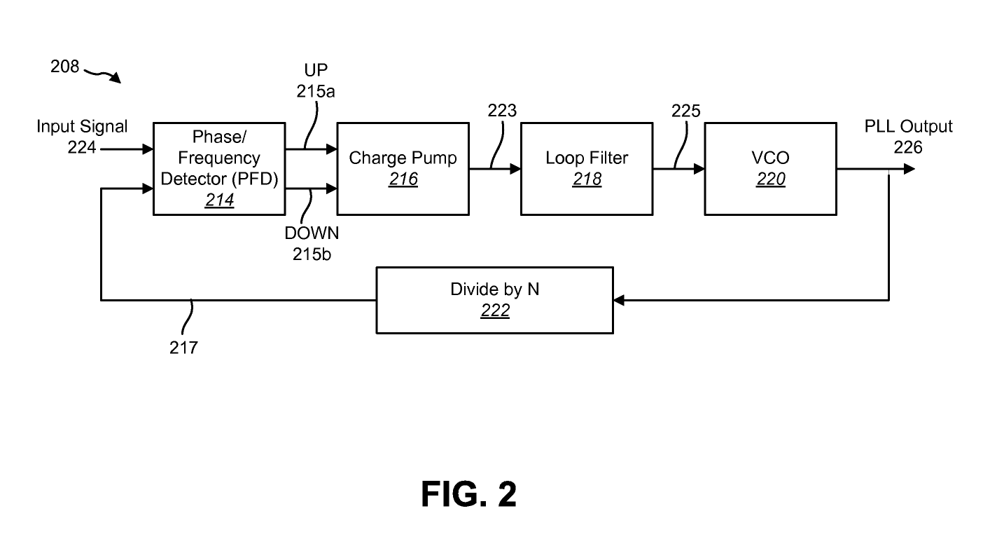

FIG. 2 is a block diagram illustrating a PLL 208 that may be used with the present systems and methods. The PLL 208 may include a PFD 214, a charge pump (CP) 216, a loop filter (LF) 218, a voltage controlled oscillator (VCO) 220, and a divide-by-N module 222. While a Phase and frequency detector 214 is described in the following configurations, a phase detector without a frequency detector may also be used. Furthermore, the PLL 208 may receive an input signal 224 and output an output signal 226.

In one configuration, the PFD 214 may compare the reference signal 224 to the output of the divide by N module 222 in the feedback loop. The output 217 of the n-divider 222 may be a signal with a frequency equal to the frequency of the output signal, PLL Output 226, divided by an integer parameter N. The parameter N may be chosen to produce a desired tuning voltage for the VCO 220. The PFD 214 may determine any differences in phase and/or frequency between the output 217 of the n-divider 222 and the reference signal 224 and express this difference as “pump up” 215a or “pump down” 215b pulses to the charge pump 216. The charge pump 216 may then provide charge to the loop filter 218 that may filter the charge pump 216 output 223 to the tuning port 225 of the VCO 220. For example, the PFD 214 may generate a digital output signal 215 including high and/or low pulses of varying lengths. The charge pump 216 may receive this signal 215 and produce an output 223 corresponding to the pump up 215a and/or pump down 215b signals from the PFD 214. The charge pump 216 output 223 may subsequently be filtered by the loop filter 218 to provide a stable voltage level input 225 to the VCO 220.

The PFD 214 output 215 may be a digital switching signal while the charge pump 216 and loop filter 218 may have analog outputs. Upon receiving a signal 225 from the charge pump 216 via the loop filter 218, the VCO 220 may generate an output 226 oscillation that is a function of the input voltage provided by the loop filter 218. The VCO 220 output, (i.e., the PLL output 226), may be fed to the PFD 214 that may then compare it with the input signal 224 and generate a phase-differential output signal. In other words, the PFD 214 may output a signal using the UP 215a and DOWN (DN) 215b signals that indicates the comparison between the input signal 224 and the feedback signal 217.

One problem with conventional PLL BIST schemes may be that the charge pump 216 and loop filter 218 output nodes are analog in nature. Therefore, any excessive loading caused by additional BIST circuitry may change the PLL 208 characteristics. The feedback loop, which typically includes a divide-by-N module 222, may be digital in nature but phase sensitive since its output 217 is fed to the PFD 214 and directly affects the phase of the PLL output 226. Any additional delay in the feedback path causes a delayed phase of the feedback signal 217 and the PLL output 226 phase, which may cause a mismatch with the input signal 224 phase. This added phase noise may be a concern in certain precision clocking applications and hence not universally acceptable in a BIST solution.

Multiple approaches to designing BIST mechanism for PLLs 208 have been attempted, each with its advantages and drawbacks. It would be desirable to provide a BIST mechanism that minimally affects internal loading conditions of the PLL 208 and uses minimal ATE 102 resources to ensure compatibility with very low cost (VLC)-ATE 102. One possible BIST scheme is an all digital BIST scheme for testing catastrophic faults in PLLs 208. Although the ATE 102 resources required may be limited in such a scheme, this provides a non-parametric gross failure screening test method. Another possible scheme is to digitally program the charge pump 216 input and observe the loop filter 218 output 225. However, this sampling of the VCO 220 input node may add excessive capacitance at that node and may affect the PLL 208 settling time characteristics. This approach also may not allow a complete self-test of the DUT 104 since some internal modules are left out of the BIST path.

Another possible BIST approach may involve adding duplicate modules or using ATE 102 to provide some of the internal node voltages. This approach also may not completely enable self-test since the stimuli are provided externally, i.e., if the loop filter 218 output/VCO 220 input is provided externally using a Per Pin Measurement Unit (PPMU) in the ATE 102, the CP 216 and LF 218 blocks may remain untested and an additional mechanism would be required to test these blocks. Since the PLL 208 is a closed loop system, self-testing of the internal modules is optimum as it reduces external resource requirements and is likely to have the minimal test time overhead.

Another possible BIST scheme may use a test controller module that can be used to control the CP 216 input in test mode. However, the PFD 214 within the PLL 208 does not drive the CP 216 and hence it is not tested in the loop. Other possible BIST schemes may include a BIST mechanism with a test mode that can select between PLL 208 output fed to the PFD 214 as against added line delay. Still another possibility is to perform parametric testing apart from simple catastrophic failure testing proposed in many other schemes. This may require additional circuits in the feedback loop and may result in some (even if minor) phase shift as well as frequency dependence on the input signal as the at-speed signal in the feedback loop is captured and used.

In addition to minimizing phase noise and external loading, the present systems and methods may ensure compatibility with the new generation of Very Low Cost—ATE (VLC-ATE) 102 developed by reducing ATE 102 functionality. VLC-ATE 102 may cost a fraction of the fully functional equipment and are increasingly used for providing low-cost solutions for production test. Maintaining test quality, in light of these limited resources available, is also addressed by the present systems and methods.

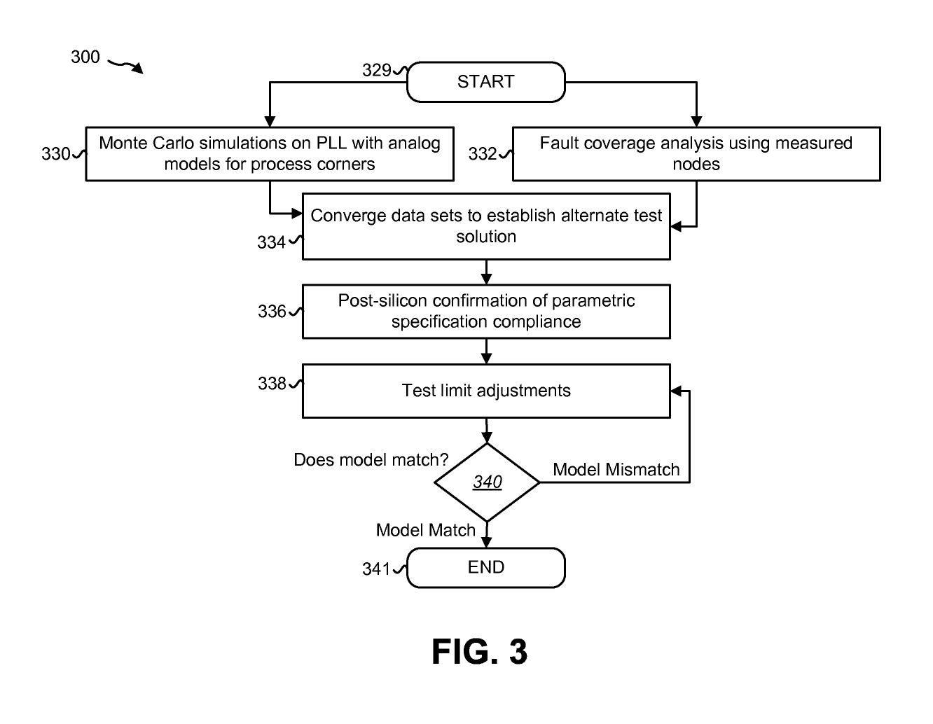

FIG. 3 is a flow diagram illustrating a method 300 for formulating an alternate test solution for a DUT 104. After the method 300 starts 329, Monte Carlo simulations may be performed 330 on the analog behavioral model of the DUT 104 across process corners to prepare a first pass system behavioral model. Similarly, fault coverage analysis may be performed 332 with the use of measured node(s). This fault coverage for a mixed signal block may be different than the typical stuck-at type of fault coverage analysis done for pure-digital circuits. The parametric fault coverage analysis performed herein is used to correlate the measurable parameter values with the system performance matrices. These two data sets may then be converged 334 in order to establish an alternate test solution. Specifically, data collected with regression models may be merged with the observed specification compliance from the behavioral models. Actual silicon samples may then be tested with data collected on all observable nodes and parametric specification compliance is confirmed 336. Test limits for the observable parameters may then be adjusted 338 to correlate with the alternate test model and the observed silicon results. Additional ATE 102 testing may be performed to obtain a larger data sample across process variation. Test limit adjustments may be performed 338 until 340 the observed data sample matches with the estimated model, after which the method 300 may end 341.

Alternate or indirect testing is a methodology used to identify and implement economical, fast and less complex tests to substitute conventional complex, specification based tests. There has been extensive work in testing analog and radio frequency (RF) subsystems with alternate testing approaches. Conventional procedures involve tests to ensure that the subsystems meet specifications, such as signal-to-noise ratio (SNR), integral non-linearity (INL) for converters, or noise figure for RF systems. There has also been research into developing fault models for analog modules and test generation based on these models. Since the correctness of analog and RF systems is defined by their adherence to a set of specifications, a fault or defect-based test is not directly applicable to them. Components in these systems may have values that are very different from the designed values, but the system may still be within specifications. This is particularly true for negative feedback systems, where the high gain of one or more operational amplifiers may counteract many problems with component values and lower gain of the blocks preceding these amplifiers.

The cost of testing for a large number of specifications can be very high. Alternate testing is an approach for analog integrated circuit (IC) testing that involves formulation of a test plan to combine statistical correlation with conventional testing methods. In alternate testing, the performance characteristics of the DUT 104 may be predicted from the outputs under a particular set of stimuli. The input stimulus may be a subset of the entire possible set of inputs and may be used only to measure certain system parameters from which the other parameters may be predicted by calculation or extrapolation. Reduction in test time and complexity is the primary goal of alternate testing and it may offer a significant cost reduction over conventional analog testing for each specification separately.

Parameter mapping can be defined as the process of mapping variation of one parameter to another correlated parameter in order find a mathematical or statistical relation between the two. Alternate testing and parameter mapping may both be applied to a complex mixed signal feedback-enabled system like a PLL 208 where multiple internal and external components affect and are dependent on the functioning of the DUT 104. The relationship between various parameters such as the PLL output 226 frequency, Fₒᵤₜ, and the VCO 220 input node voltage, V_{ctrl}, may be described in equation (1) as follows:

Fₒᵤₜ=a₀+a₁V_{ctrl}+a₂V²ctrl+a₃V³ctrl+ . . . (1)

where a₀, a₁, etc. have deterministic values. Some other parametric relationships such as the one between transistor current drive, n/p_{I-drive} and PLL 208 locking time, T_{lock}, may be statistical in nature.

Some parametric relations, discrete in nature, may not fit a deterministic functional relation but may be represented as matrices (shown in equation (2)) where the matrix A_{i x k} represents the transfer relation between an input set I_{k x j} and a response set F_{i x j}

Fᵢₓⱼ=Aᵢₓₖ [symbol] Iₖₓⱼ(2)

Alternate testing principles may be applied to any mixed signal circuit with multiple internal nodes, where the nodes and output are inter-dependent. Parametric relations between various internal nodes and the functional output for a PLL can be explained as follows: when an input frequency signal at frequency fₒₚᵣ is applied to a PLL 208 with a loop multiplier of 1, the PLL 208 attempts to latch to the input frequency and phase within the time interval t_{latching}. The phase detector 214 signal is instantaneously proportional to the phase and frequency difference between fₒₚᵣ and the PLL output 226 signal at the measurement instant t′. This dependence may be represented as shown in equation (3) as follows:

P[fₒₚᵣ,f_{PLL}t′] [symbol] P[PDₒᵤₜ,t′] (3)

where P[p1]→ (is the) parametric space matrix for parameter p1. The parametric set P[PDₒᵤₜ,t′] is finitely bound and can be well characterized using SPICE simulations for all the independent variables in Equation (3). The set of [PDₒᵤₜ] is a bijective function of [fₒₚᵣ,t′] with a finite deterministic statistical confidence for a stable and functional PLL during lock-mode. The value f_{PLL} may be the frequency of the PLL output 226. Values such as phase detector 214 output (PDₒᵤₜ), charge pump 216 output (CPₒᵤₜ), loop filter 218 output (LFₒᵤₜ), and voltage controlled oscillator 220 output (VCOₒᵤₜ) may be the output signals of the PFD 214, the CP 216, the LF 218, and the VCO 222, respectively. The value of [PDₒᵤₜ] may be predicted with certain statistical confidence at an instant t′ if the variables operational frequency fₒₚᵣ and PLL frequency f_{PLL} can be measured.

Similar relationships may exist between the remaining internal system nodes. The CPₒᵤₜ signal may be a function of the PFD output 226 and when considered over an interval [0,t′], it may be a bijective relation represented by the following equation (4):

P[PDₒᵤₜ,0,t′] [symbol] P[CPₒᵤₜ] (4)

The LF 218 and VCO 220 may have similar bijective relations as shown in equation (5):

P[CPₒᵤₜ,0,t′] [symbol] P[LFₒᵤₜ,0,t′] (5)

The bijective relationship between the CP 216 and the LF 218 may be established over a specified time interval [0,t′] since the node voltages are analog in nature and are a function of the measurement window during PLL 208 locking process.

P[LFₒᵤₜ] [symbol] P[VCOₒᵤₜ] (6)

The bijective relationship between the LF 218 and the VCO 220, shown in equation (6), may be established instantaneously (while including propagation delays) and may represent the relationship between the voltage node and the effective frequency output.

The present systems and methods may use the bijective relationship in equation (4) to perform parametric testing of the PLL 208. While accessing the common node between the PFD 214 and the CP 216, the remaining PLL 208 may be treated as a closed loop with successive bijective-related sub blocks, e.g., the LF 218, the VCO 220, and the divide by N module 222. An input vector i[CPᵢₙ], which is a subset of the vector set P[CPᵢₙ], may be applied to the CP 216 using an external driver. Furthermore, the corresponding output vector from the PFD 214, i[PDₒᵤₜ], may be recorded. The vector i[PDₒᵤₜ] may then be integrated over a time interval [0,t′] and compared with simulation data to compare the accumulated voltage value. The bijective relations are valid for this analysis as we inject the CPᵢₙ vector and observe the closed loop response on PDₒᵤₜ node, isolated by using the test mode. By including the tolerance limits for the value of the integrated vector i[PDₒᵤₜ], a pass/fail decision can be made by the ATE 102.

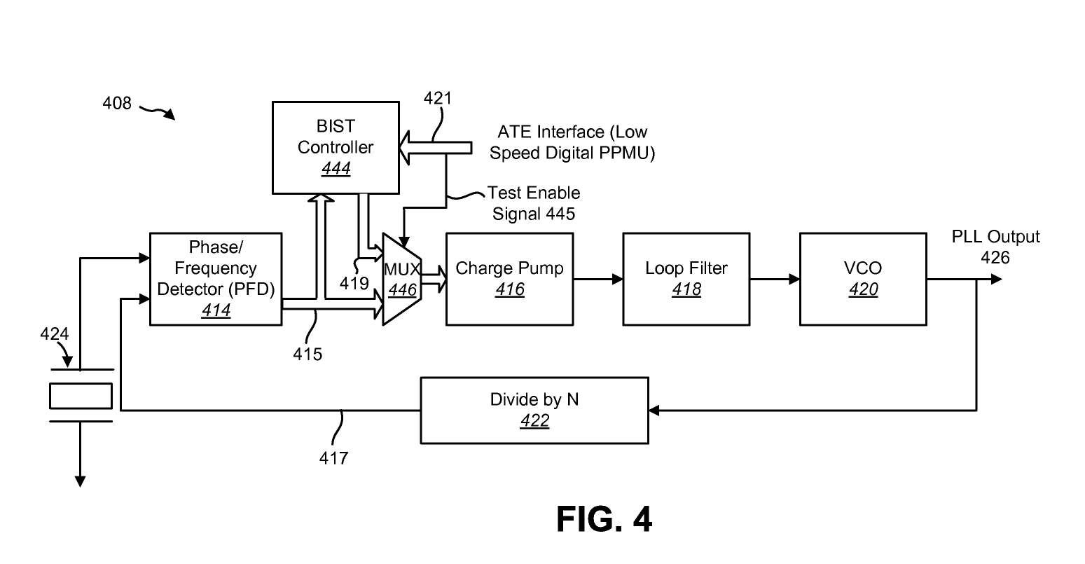

FIG. 4 is a block diagram illustrating a system for a PLL 408 BIST. In light of the problems with current PLL 408 BISTs, the systems and methods described herein may have the following goals: (1) to complete self testing of all blocks, i.e., the entire feedback system loop is to be maintained during the test; (2) to not disturb any sensitive analog or digital nodes with added circuitry; (3) to generate most required internal stimuli by the DUT 104 to ensure that no individual blocks need to also be tested externally; (4) to be compatible with low functionality VLC-ATE 102 to contain production test cost while optimizing area overheads; (5) to be independent of the PLL 408 operating frequency; and (6) to enable parametric and alternate testing methods. Various configurations of the present systems and methods may not necessarily achieve the above goals.

Accordingly, the present PLL 408 BIST scheme may include a BIST controller 444 that may act as a programmable stimulus generator and an observation module. The BIST controller 444 may be positioned between the PFD 414 and the CP 416. The PLL 408 may include a charge pump 416, loop filter 418, VCO 420, and divide by N module 422 illustrated in FIG. 4 that operate similarly to the charge pump 216, loop filter 218, VCO 220, and divide by N module 222 described in FIG. 2. The digital output 415 of the PFD 414 may be fanned out to the BIST controller 444 in parallel with the mission mode connection to the CP 416. Output 419 from the BIST controller 444 may be fed to the CP 416 through a multiplexer 446 that is connected to the PFD 414 during mission mode and to the BIST controller 444 during test mode. A test enable signal 445 may be provided by the ATE 102 to enable multiplexing. The ATE 102 control/data signals 421 that connect to the BIST controller 444 are represented by a bus that includes either analog-PPMU-type or low frequency digital signals. The digital code 421 that is to be fed to the CP 416 to perform controlled charging of the VCO 420 input, via a loop filter 418, may be scanned in serially. In other words, the high/low nature of the digital input, from the PFD 414 or the BIST controller 444, may control the conduction of the CP 416 switches. The BIST controller 444 may also read in the PFD 414 output 415 for a specified duration after feeding in the CP 416 code 421 and this signal on the PFD 414 output 415 may be fed to a low pass filter (LPF) to generate a DC voltage level internally. Then, the PLL output 426 may again be processed by the divide by N module 422 and fed back 417 into the PFD 414, after which the PFD 414 output 415 may again be read by the BIST controller 444, filtered by a LPF, and measured as a DC voltage value. The DC voltage value may be compared to simulated data to determine whether the PLL 408 is operating correctly. A VLC-ATE 102 PPMU may then be used to measure this DC voltage value. The input pin used to scan in the CP 416 programming code 421 may be designed to be an input/output pin that is also used for this PPMU measurement.

For example, when the PLL 408 is started from a sleep mode, the input signal 424 may already be at speed. In one configuration, the input/reference signal 424 with a predetermined frequency may be provided by a crystal oscillator and/or another suitable signal generator. At that point, the PFD 414 may compare the feedback 417 to the input signal 424. Since the PLL output 426 frequency may be zero at the beginning, the PFD 414 may send an UP signal 415 to the CP 416. In turn, the CP 416 may increase the voltage that is input to the VCO 420 via the loop filter 418. The VCO 420 may then output a higher PLL output 426 frequency. This loop may repeat multiple times until the PLL output 426 frequency is locked to the input signal 424. Thus, the PFD 414 output 415, when accumulated in the BIST controller 444 during production testing, may create a signature of ramping up. The ATE 102 may monitor this signature to determine whether the PLL 408 is operating correctly within established parametric specifications. In other words, if the accumulated PFD output 414 voltage does not ramp up or ramps up too quickly or slowly, this may indicate a problem with the PLL 408 operation.

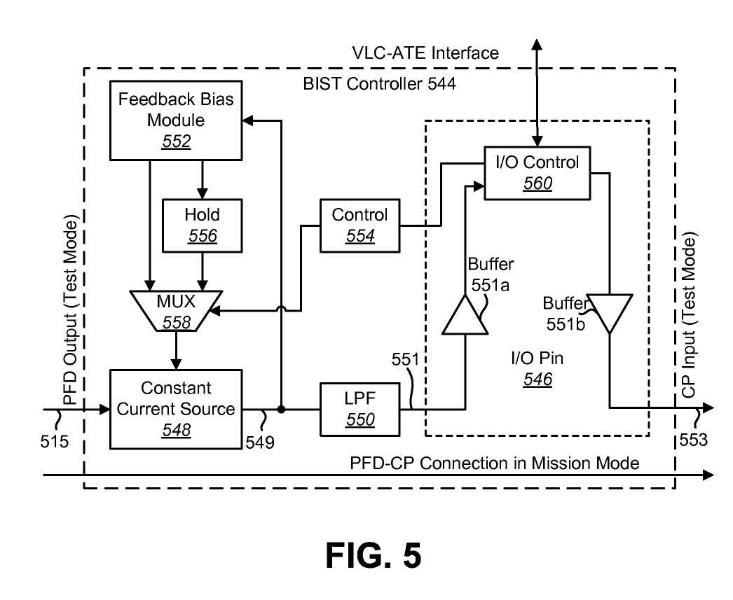

FIG. 5 is a block diagram illustrating a BIST controller 544. The input section of the BIST controller 544 may actually be the I/O pin 546 of the DUT 104 that is used to scan in digital data onto the CP 416 input and to read out the parametric output data on a PPMU. The I/O pin 564 may also include I/O buffers 551a-b. The I/O control module 560 may enable two way communication between the I/O pin 546 and the ATE 102. In other words, no additional modules (i.e., silicon area) may be required for the input section of the BIST controller 544 because the input functionality may be limited to mitigating digital waveforms forced by the ATE 102 to the inputs of the CP 416. The multiplexer 446 in FIG. 4 may route the BIST controller 544 to the CP 416 instead of the PFD 414 during test mode.

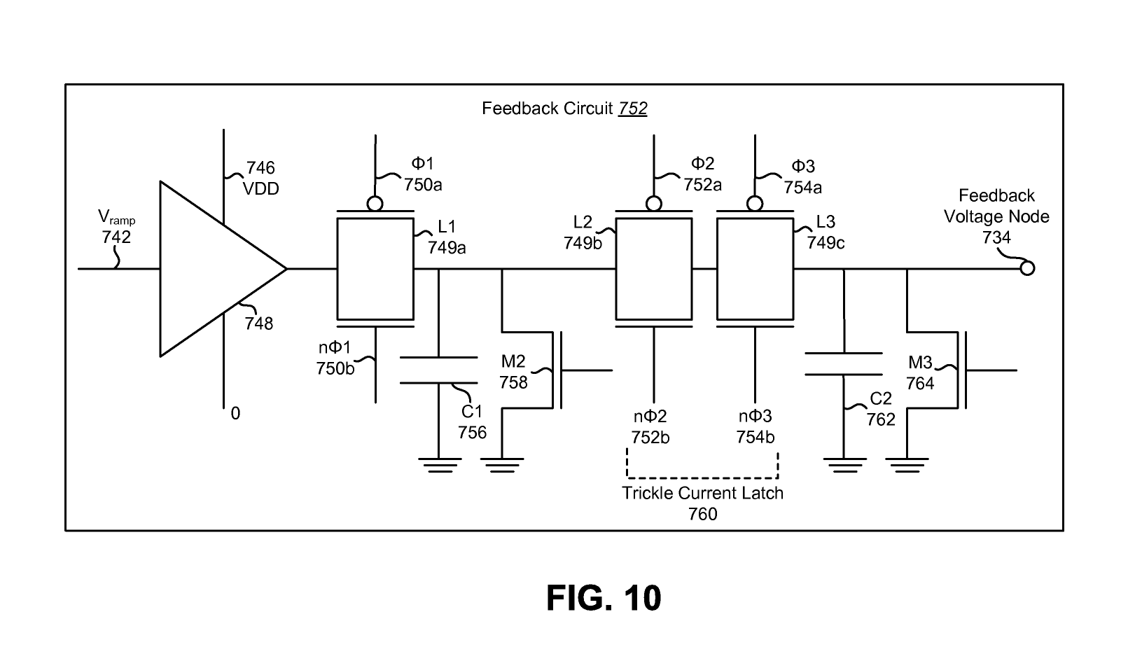

As mentioned above, it may be desirable for a BIST scheme to have process independence to ensure that the integration process yields identical results in case of multiple process corners. A feedback bias mechanism 552 may be used to calibrate the constant current source 548 for process variation. This may help achieve a process-compensated input to the low pass filter 550. The feedback bias module 552 is discussed in further detail below in relation to FIG. 10. The feedback bias module 552 may receive the output 549 from the constant current source 548 in test mode. The control module 554 may provide the control signals, via a multiplexer 558, to perform process-independent calibration and then to switch over to test mode from calibration mode where the voltage representation of the PFD output 515 is produced. The control module 554 thus switches over to the hold circuit 556 to provide a set bias voltage once the calibration process is complete and the actual test process is started.

In test mode, the output 515 of the PFD 414 may be fed into the BIST controller 544 and used to control and drive a constant current source 548. This output 549 is then integrated over the test duration, which can be programmed by the control signals fed in from the ATE 102. When the test mode input is activated by the control module 554, data pulses may be forced into the CP 416 input 553 through the ATE 102 I/O interface. The duration of the input pulses may be controlled by the ATE 102 and may be programmed depending on the DUT 104 specifications and characterization results. A pulse applied on the CP 416 input 553 may connect the CP 416 output node to VDD or ground depending on the input used, thus providing a charging or a discharging path to the CP 416 load. The conductivity of the transistors used in the CP 416 as well as the input pulse duration may affect the net charge interchange that can occur during test mode. In other words, Q_{chrg/dischrg}=f[_{TransistorConductivity,InputPW,LFLoad}] where the factors TransistorConductivity and LFLoad are dependent on the process corner targeting of the DUT 104 and may be reliably used as qualitative parameters for process corner prediction if the input pulse width is maintained constant.

If a pulse of τ is applied to the CP 416 during test mode during DUT 104 initialization, the loop filter 418 capacitor may be charged to a voltage V_{LFout} which can be represented by equation (7):

V_{LFout}=Q_{LF}/C_{LF}=∫₀^{τ}I_{LFdrive}/C_{LF} (7)

where Q_{LF} is the charge on the loop filter 418 capacitor, C_{LF} is the capacitance of the loop filter 418 capacitor, and I_{LFdrive} is the current used to drive the loop filter 418. In case of catastrophic failures in the CP 416, the LFₒᵤₜ node may remain at ground level when the DUT 104 is initialized. Any marginalities/process variation in the CP 416 may result in an LF 418 output that can be denoted by equation (8):

V_{LFout}±δV_{LFout}=∫₀^{τ}[I_{LFdr}±δI_{LFdr}]/[C_{LF}±δC_{LF}] (8)

Since the BIST controller 544 may not have access to the CP 416 output node or the LF 418 output node in the PLL 408 in the BIST scheme, this parametric variation in the LF 418 output/VCO 420 input may be verified during design phase for multiple process corners. The present systems and methods, using a full-self test approach, now tests the following blocks with a parametric variation at the VCO 420 input. The VCO 420 output frequency in test mode may be given by equation (9):

F_{VCO}=f[V_{LFout}] (9)

where F_{VCO} is the frequency of the VCO 420 output and V_{LFout} is the voltage of the LF 418. The values V_{PDout}, V_{CPout}, and V_{VCOout} may be the voltage level of the outputs of the PFD 214, CP 216, and VCO 220, respectively. Therefore, any variation in the VCO 420 output frequency may be parametrically traced to the LF 418 output variation using equations (10) and (11):

F_{VCO-min}=f[V_{LFout-min}] (10)

Equation (11) is as follows:

F_{VCO-max}=f[V_{LFout-max}] (11)

As the VCO output frequency is a directly proportional function of the LF output signal, minimum and maximum VCO frequencies may be described in equations (10) and (11).

The sequence of pulses 515 generated by the PFD 414 for this VCO 420 input signal may be a function of the frequency and phase difference between the VCO 420 output 426 and the frequency of the input/reference signal 424. Thus, when passed through an LPF 550 or integrated over a specified duration, the pulses may represent the exact frequency difference between these two signals, thus creating a DC representation of the VCO 420 output frequency 426 as described in equation (12).

$${\int }_{0}^{t 1} {V}_{PDout} = f [ {F}_{VCO} ] \qquad ( 12 )$$

Therefore, effectively,

$${\int }_{0}^{t 1} {V}_{PDout} = f [ {F}_{PD} , {F}_{VCO} , {F}_{LF} , {F}_{LFdr} ] \qquad ( 13 )$$

where voltage at the PFD 414 output node is a function of and is dependent upon the working of PFD 414, VCO 420, and LF 418 blocks. A catastrophic failure in any of the sub-blocks in the PLL 408 is detectable by Equation (13). Parametric or specification failures in any of the sub-blocks may also be identified with Equation (13).

It may be desirable to ensure that any of the additional components added in a BIST scheme do no influence this transfer function. The use of the constant current source 548 output 549 that is stabilized for process variation to drive the LPF 550, instead of directly using the PFD 414 output 515 to drive the load, may be for this purpose. Any process variation causing component value mismatch in the LPF 550 may affect the final output voltage 551 of the LPF 550 and not accurately represent the internal modules. The PFD 414 output signal 515 is thus used to switch the process-stabilized constant current source 548 and LPF 550 combination, eliminating effects of process variation from the externally added BIST circuits.

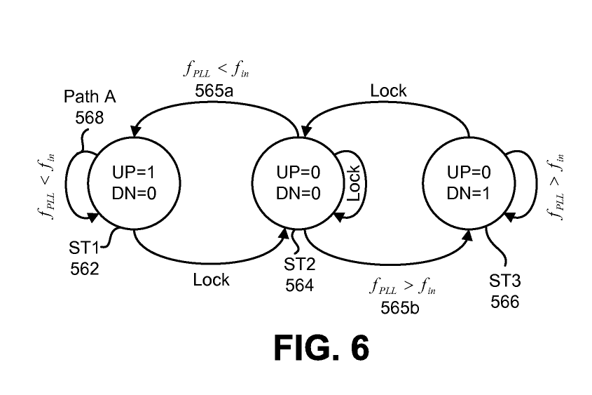

FIG. 6 is a state diagram for a PLL 408 BIST test mode. The state machine is illustrated in terms of the Pₒᵤₜ/CPᵢₙ nodes (515 and 553, respectively) and corresponding signal values. A locked PLL 408 requires no additional charging or discharging of the VCOᵢₙ node 225 and hence this state is represented by ST2 564 (i.e., PDₒᵤₜ UP signal=0, and the PDₒᵤₜ DN signal=0). This is the stable and locked state of the PLL 408. Depending on the PFD 414 design, ST2 564 may be metastable, i.e., where successive charging and discharging cycles are provided to the CP input to maintain charge neutrality. For example, the PFD 414 may alternate between [UP=1;DN=0] and [UP=0;DN=1] so that the net effect on the CP 416 input node is equivalent for each UP and DN, effectively conserving the charge at CPₒᵤₜ while the PLL 408 remains in the lock state. The net PDₒᵤₜ signal in this case is [UP=½; DN=½], when averaged over two successive cycles. This may be identical in effect to the [UP=0; DN=0] condition required for lock stability. Any charging or discharging required for the VCO 420 input node to increment or decrement the VCO 420 frequency is represented in FIG. 6 by the states ST1 562 [UP=1;DN=0] and ST3 566 [UP=0;DN=1], respectively. In other words, if f_{PLL} becomes smaller than fᵢₙ while locked, the PLL 408 may transition 565a to state ST1 562, i.e., charge up with a [UP=1; DN=0] signal from the PFD 414. However, if f_{PLL} becomes larger than fᵢₙ while locked, the PLL 408 may transition 565b to state ST3 566, i.e., charge up with a [UP=0; DN=1] signal from the PFD 414.

The BIST scheme may force the CPᵢₙ along Path A 568 when in test mode. This path may be forced externally, and the corrective signal produced by the comparison between f_{PLL} and fᵢₙ does not affect the CP 416 in test mode.

This state-machine-control may be used in test mode operation and the PLL 408 may translate between the ST1 562, ST2 564, and ST3 566 during mission mode, depending on the concerning circuit conditions.

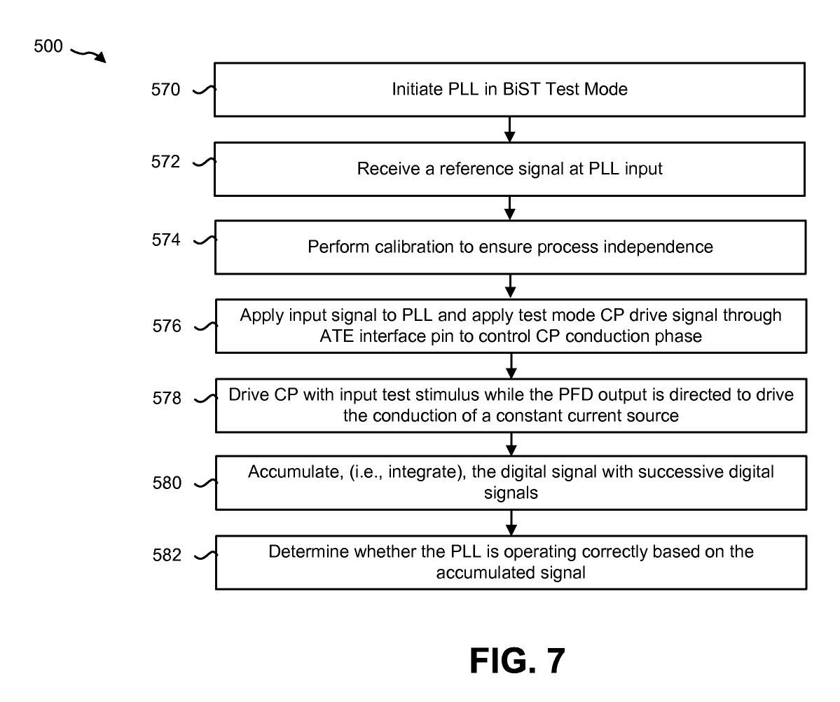

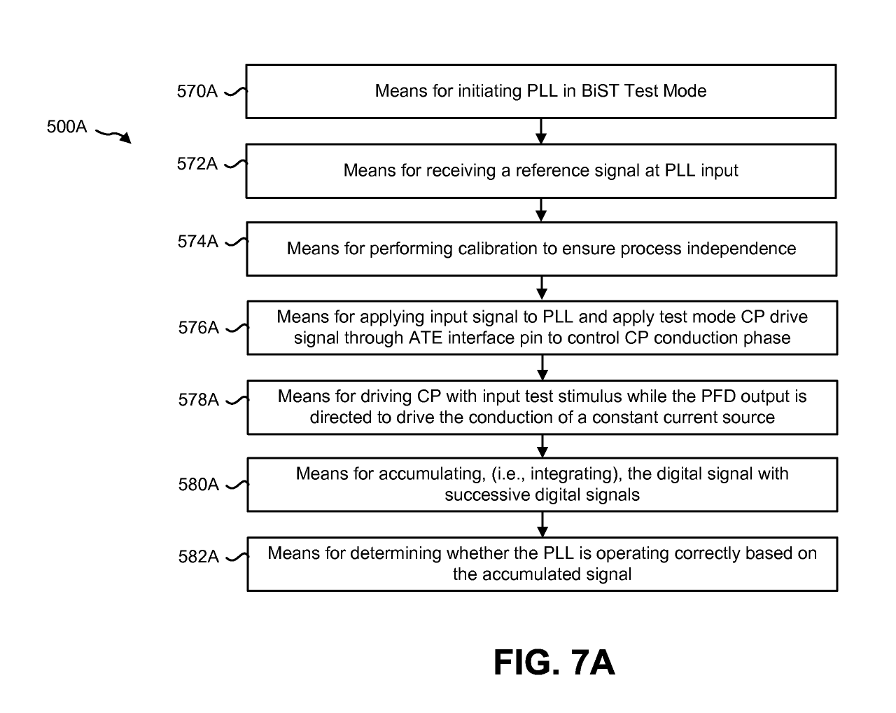

FIG. 7 is a flow diagram illustrating a method 500 for a phase locked loop 408 built in self test. The method 500 may be performed in a PLL 408. After the method 500 starts 570, the PLL 408 may receive 572 a reference signal 424. The reference signal 424 may have a predetermined frequency and may be provided by a crystal oscillator and/or another suitable internal signal generator. The PLL 408 may be calibrated 574 at the beginning of the test mode operation where the internal current source 548 is calibrated with a dynamic feedback system to achieve a constant conduction rate. Two different signals may be used. First, the mission mode external input signal may be applied 576 to the PLL input pin. Second, the BIST controller 444 may connect the CP 416 input to the externally applied test stimulus, i.e., the BIST controller 444 may apply 576 a test-mode stimulus signal from the ATE 102 to control the CP 416. This test stimulus, applied using the ATE I/O resources 546 may be directed by the I/O control module 560. The test stimulus may control the conduction of the CP 416 and the CP 416 output, when integrated by the loop filter 418, produces a DC voltage level, which may be a faithful reproduction of the signature of the input signal applied.

The VCO 420 may output a PLL output 426 with a frequency that corresponds to the voltage level VCO 420 input. The PLL output 426 may then be fed back, through a divide by N module 422. This signal is received by the PFD 414, which may generate an output signal 415 after comparing this PLL output 426 for test-mode-stimulus with the PLL input signal 424. The integrated value of this PFD 414 output signal is a function of the integrated PLL output 426 characteristics as the PLL input 424 remains unchanged. In BIST test-mode, the PFD output 415 is fed to the BIST controller 444 and may be used to drive 578 the conduction of the process compensated constant current source 548. The output of this constant current source 548 may be integrated 580 within the BIST controller 544 and output on the DUT 104 I/O pin by using the I/O control module. This output may be available on the DUT 104 I/O pin and may be read by the VLC-ATE PPMU to obtain DC content value. So, the CP 416 may be driven 578 by the test stimulus signal while the PFD output 415 is used to drive the constant current source 548. In other words, each output of the PFD 414 may be accumulated 580 in a BIST controller 444 located in between the PFD 414 and the CP 416. This accumulated signal may then be analyzed against simulated data to determine 582 whether the PLL 408 is operating correctly. In other words, during normal operation start up, the PFD 414 may be expected to continually output a pump up signal [UP=1; DN=0]. However, if the PFD 414 output accumulates too quickly or too slowly, this may indicate a problem with the PLL 408 operation. The determining 582 may be performed in ATE 102.

The method 500 of FIG. 7 described above may be performed by various hardware and/or software component(s) and/or module(s) corresponding to the means-plus-function blocks 500A illustrated in FIG. 7A. In other words, blocks 570 through 582 illustrated in FIG. 7 correspond to means-plus-function blocks 570A through 582A illustrated in FIG. 7A.

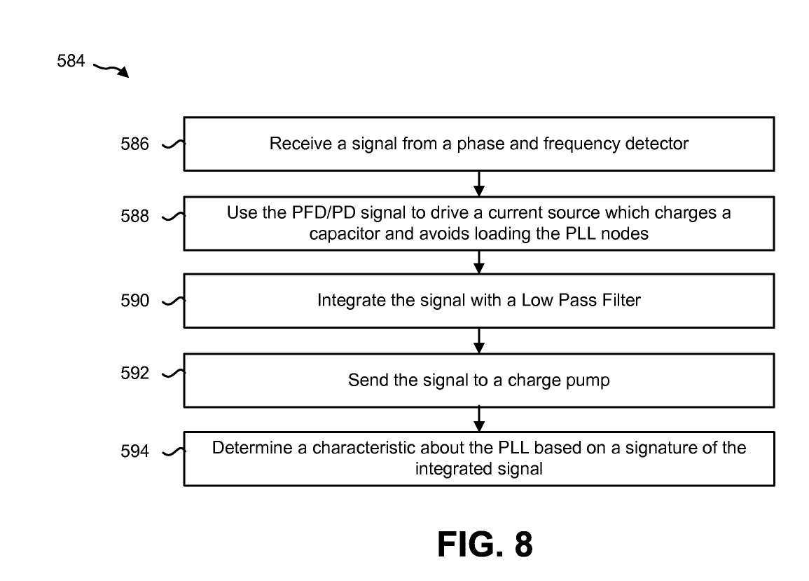

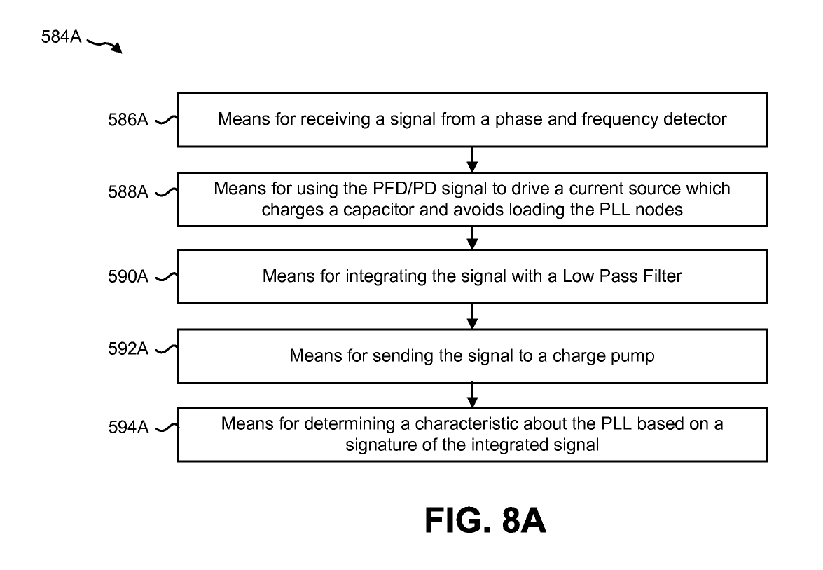

FIG. 8 is another flow diagram illustrating a method 584 for a phase locked loop 408 built in self test. The method 584 may be performed in a BIST controller 444 in a PLL 408. In other words, the steps of the method 584 in FIG. 8 may be performed alternatively or in addition to steps 580 and 582 in the method 500 in FIG. 7. The BIST controller 444 may receive 586 a signal from a PFD 414. This signal may indicate the difference in phase and/or frequency between a reference signal 424 and a feedback signal in the PLL 408. The signal drives a process compensated constant current source 548, which charges 588 a capacitor with its output to avoid loading the PLL 408. The BIST controller 444 may integrate 590 the signal with a low pass filter 550. The BIST controller 444 may send 592 the signal to the CP 416 to produce a PLL output 426 that may be fed back into the PFD 414. The BIST controller 444 may also determine 594 a characteristic about the PLL 408 based on a signature of the integrated signal. In other words, the BIST controller 444 may determine if the PLL 408 is operating correctly based on whether, and how quickly, the integrated PFD 414 output signature matches simulated data for PLL 408 production testing. Alternatively, the determining 594 may be performed in ATE 102.

The method 584 of FIG. 8 described above may be performed by various hardware and/or software component(s) and/or module(s) corresponding to the means-plus-function blocks 584A illustrated in FIG. 8A. In other words, blocks 586 through 594 illustrated in FIG. 8 correspond to means-plus-function blocks 586A through 594A illustrated in FIG. 8A.

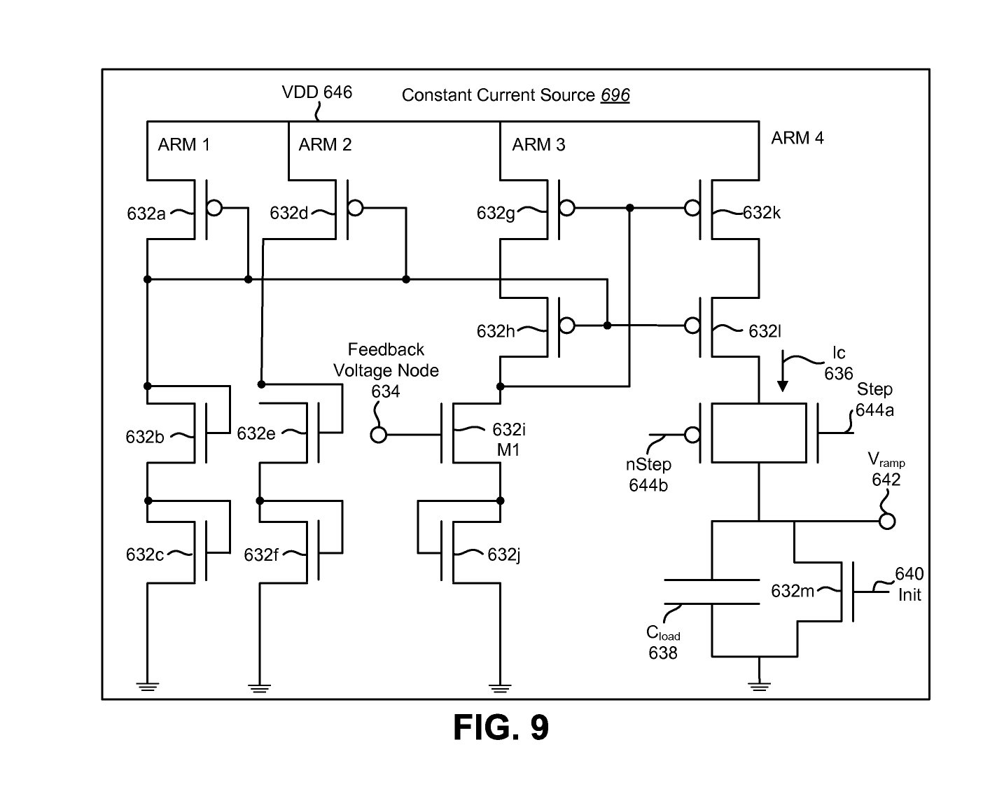

FIG. 9 is a circuit diagram illustrating one configuration of a constant current source 696 for use in the present systems and methods. One advantage of using a constant current source 696 driven LPF 550, as shown in FIG. 5, is that it may remove process variables out of the added BIST circuitry. The constant current source 696 may be designed for this application and the current drive may be adjusted to not reach Vₛₐₜ or VDD 646 during test interval τ so that a discrete voltage level representing conduction phase of the PFD 414 output is generated by this constant current source 696 charging a load. A non-process-compensated current mirror circuit is represented in FIG. 9. If this circuit is used without the feedback compensation, its performance may be affected by the process variation, making it of limited use to a process-robust BIST scheme.

The constant current source 696 may feed an ideal capacitor serially. The constant current source 696 may be implemented using multiple transistors 632a-m arranged in a fashion to produce a constant current 636, as shown in the circuit diagram of FIG. 9. A current mirror circuit using semi-telescopic topology may produce the constant current 636. For the constant current source 696 to have process-independent charging characteristics, a precise current and capacitance value may be essential. In other words, process variations may affect the current drive of the circuit, thus varying input to the LPF 550.

Constant current charging of a capacitor C linearly increases the voltage across the plates. Any process variation causing a change in capacitance would inversely affect the ramp voltage slope. Similarly any variation in the current drive of the charging circuit would affect the charging time as shown in Equation (14):

$$C = \frac{Q}{V} , {V}_{cap} ∝ \frac{1}{C} . \qquad ( 14 )$$

Hence, Equation (15):

$$δ {V}_{cap} ∝ \frac{1}{δ C} . \qquad ( 15 )$$

where C represents capacitance for a capacitor, Q represents charge across the capacitor, and V represents voltage across the capacitor. SPICE simulations run for cold-nominal-hot process corners indicate that for the ramp generator without feedback, a very precise process target may be required to maintain the required ramp slope, making it impractical for production testing 112. A feedback scheme may provide controllability of the ramp. The feedback scheme may be a variable feedback that can maintain a constant voltage ramp slope for process variations in the capacitor or constant current source circuit. This feedback may be dynamic to ensure complete process corner independence.

The use of multiple clocks may limit multi-site production testing. Furthermore, VLC-ATE 102 may have a limited number of clocking resources available. To maintain low-cost ATE 102 compatibility, the components on the integrated circuit 106 may need to use clocks with a 50 percent duty cycle. The high speed asynchronous clocks available on VLC-ATE 102 may be free running PLL 408 outputs. A 50 percent duty cycle PLL-generated clock may be produced on most VLC-ATE 102 at the required high frequencies. Using phase-shifted limited duty cycle clocks may require greater system resources and may not be within the capabilities of a typical VLC-ATE 102. No additional (or negative) power supplies are required for the PLL 408 BIST apart from the native supplies for the analog-to-digital converter (ADC)/buffers.

The constant current 636 may then be applied to a capacitor C_{load} 638. In one configuration, C_{load} 638 may be a 10 picoFarad (pF) capacitor. The voltage across C_{load} 638 may be referred to as Vᵣₐₘₚ 642. The voltage across C_{load} 638 may increase linearly as the constant current 636 charges C_{load} 638. An initialization signal Init 640 may be provided to the ramp generator 696 to initiate production testing 112.

The constant current source 696 may receive feedback from a feedback circuit 552. The gate bias for transistor M1 632i may depend on the feedback circuit 552. For example, the gate of transistor M1 632i may be set to the feedback voltage node 634. An increase in the feedback voltage node 634 may decrease the constant current 636 of the constant current source 696. A decrease in the constant current 636 may increase the charging time of the capacitor C_{load} 638. Likewise, a decrease in the feedback voltage node 634 may increase the constant current 636 of the constant current source 696 and decrease the charging time of the capacitor C_{load} 638. The charging time of the capacitor C_{load} 638 may also be referred to as the settling time of the constant current source 696. The settling time for the constant current source 696 may be a factor in production testing 112 because testing may not begin until a consistent ramp slope has been obtained. Therefore, it may be desirable for the output ramp to stabilize in the minimal possible time. The constant current source 696 may receive Step 644a and nStep 644b. Step 644a and nStep 644b may be fed the system differential clock in order to enable conduction of the constant current to C_{load} 638. Step 644a and nStep 644b may prevent C_{load} 638 from charging during a reset phase when C_{load} 638 is shorted using Init 640 with transistor 640m. This prevents a short circuit and excessive current flow through C_{load} 638.

FIG. 10 is a circuit diagram illustrating one configuration of a feedback circuit 752 for use in the present systems and methods. The feedback circuit 752 may be one configuration of the feedback bias module 552. The input of the feedback circuit 752 may be tied to the output Vᵣₐₘₚ 742 of the constant current source 696. A clocked comparator 748 may be used to compare the ramp output Vᵣₐₘₚ 742 with VDD/2 at the time Tper/2, where Tper is the ramp period.

Transistor M2 758 may be used to reset capacitor C1 756. Capacitor C1 756 may be used as a per-cycle-charge-storage for the clocked comparator 748 output. If Vᵣₐₘₚ 742 is less than VDD/2 at Tper/2, the voltage across C1 756 may be set to VDD 746. Otherwise, the voltage across C1 756 may be set to 0 volts. The feedback circuit may also include multiple latches L1 749a, L2 749b and L3 749c. Latch L1 749a may be controlled with a clocking resource that has phases φ 750a and nφ1 750b. Latch L2 749b may be controlled with a clocking resource that has phases φ2 752a and nφ2 752b. Latch L3 749c may be controlled with a clocking resource that has phases φ3 754a and nφ3 754b. Latches L2 749b and L3 749c may be referred to as a combination latch or a trickle current latch 760. Latches L2 749b and L3 749c may be toggled by an offset clock to limit the conductive phase of the combination latch such that the offset phase φ3 754a is given by Equation (16):

φ3=φ1∩φ2. (16)

Phase φ2 752a and φ3 754a may be generated by using a single clocking resource—the phase difference generated by adding wide-gate delay. Phase φ3 754a lags phase φ2 752a by this delay amount. This phase offset limits the effective conduction cycle through this dual-latch as explained in Equation (16). The offset phase φ2 752a may be generated out of an oversized gate delay such that no clocking source overhead is required. When L2 749b and L3 749c conduct, C1 756 is connected in parallel with a second capacitor C2 762, and a charge sharing current, I_{charge-sharing}, flows to equalize the voltage across each capacitor according to Equation (17):

$${I}_{charge - sharing} = \frac{d}{d t} [ \frac{{v}_{1} - {v}_{2}}{{c}_{1} + {c}_{2}} ] . \qquad ( 17 )$$

where V1 is the voltage across capacitor C1 756 and V2 is the voltage across capacitor C2 762. The voltage across capacitor C2 762 may be used to change the bias current in the constant current source 696 because the voltage across capacitor C2 762 is the feedback voltage node 634, 734 applied to the gate of transistor M1 632i from FIG. 9 above. The voltage across capacitor C2 762 may also be referred to as Vᵣₐₘₚ742. If Vᵣₐₘₚ 742 is less than a reference voltage V_{ref} in the clocked comparator 748 at Tper/2, C1 756 may charge C2 762 to a higher voltage value. If Vᵣₐₘₚ 742 is greater than V_{ref} at Tper/2, the voltage across C1 756 may be set to 0 volts, and C1 756 may partially discharge C2 762, lowering the effective voltage across C2 762. A reduction in voltage across C2 762 means a lower gate bias for the current mirror used in the constant current source of FIG. 9, thereby reducing the load charging current 636.

C1 756 and C2 762 may each be designed to be approximately 1 picoFarad (pF) to minimize the layout area overhead. Using wide transistors for the latches L2 749b and L3 749c may enable rapid charge sharing between C1 756 and C2 762 due to increased conductivity. Using wide transistors for the latches L2 749b and L3 749c may also result in Vᵣₐₘₚ overshoot and undershoot, as excessive correction bias may be applied to the constant current source 696. The transistor widths for the latches L2 749b and L3 749c may be optimized to stabilize Vᵣₐₘₚ 742 in approximately 6-7 cycles. The reference voltage V_{ref} in the clocked comparator 748 may typically be maintained at VDD/2 and may be generated on the integrated circuit 106 by matched load sharing. Transistor M3 764 may provide a reset option for the feedback biasing voltage when the circuit is initialized.

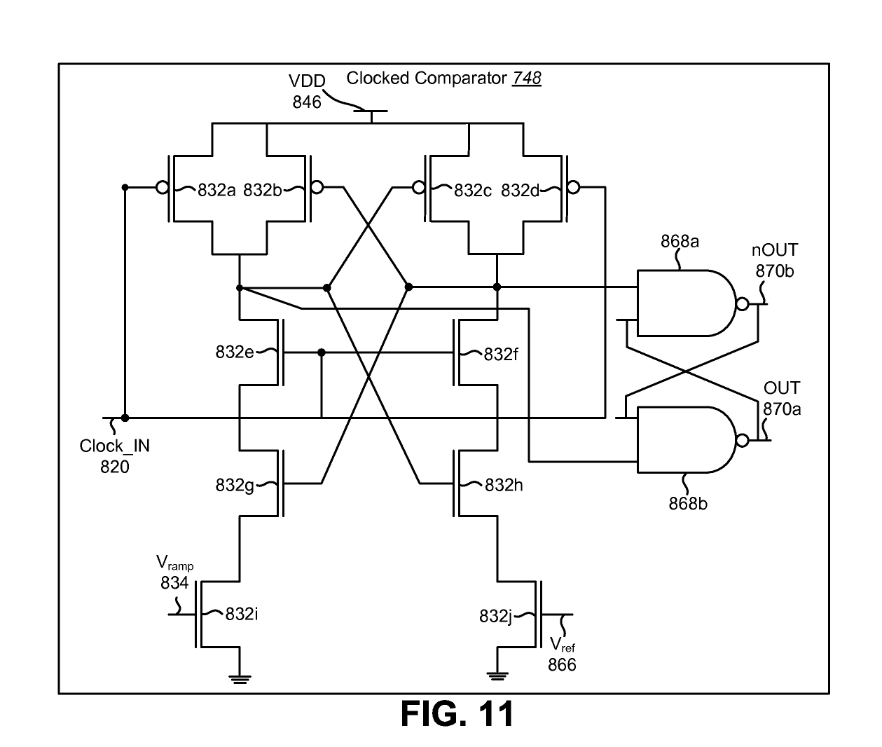

FIG. 11 is a circuit diagram illustrating one configuration of a clocked comparator 748 for use in the present systems and methods. The clocked comparator 748 may be used as part of the feedback circuit 752. The clocked comparator 748 may include multiple transistors 832a-j connected between VDD 846 and ground, along with two NAND gates 868a, 868b, as shown in FIG. 11. The clocked comparator 748 may use a Clock_IN 820 to control two of the transistors 832a, 832d.

The clocked comparator 748 may receive Vᵣₐₘₚ 834 as the gate voltage to transistor 832i. The clocked comparator 748 may also receive V_{Ref} 866 as the gate voltage to transistor 832j. As discussed above in relation to FIG. 10, the clocked comparator 748 may output 870a a voltage VDD 846 if Vᵣₐₘₚ 834 is less than VDD/2 at Tper/2. Otherwise, the clocked comparator 748 may output 870a a voltage of 0 volts. Outputs 870a and 870b are mutually inverted and either of the two may be used in the feedback path, depending on the application. The remaining output may remain unused.

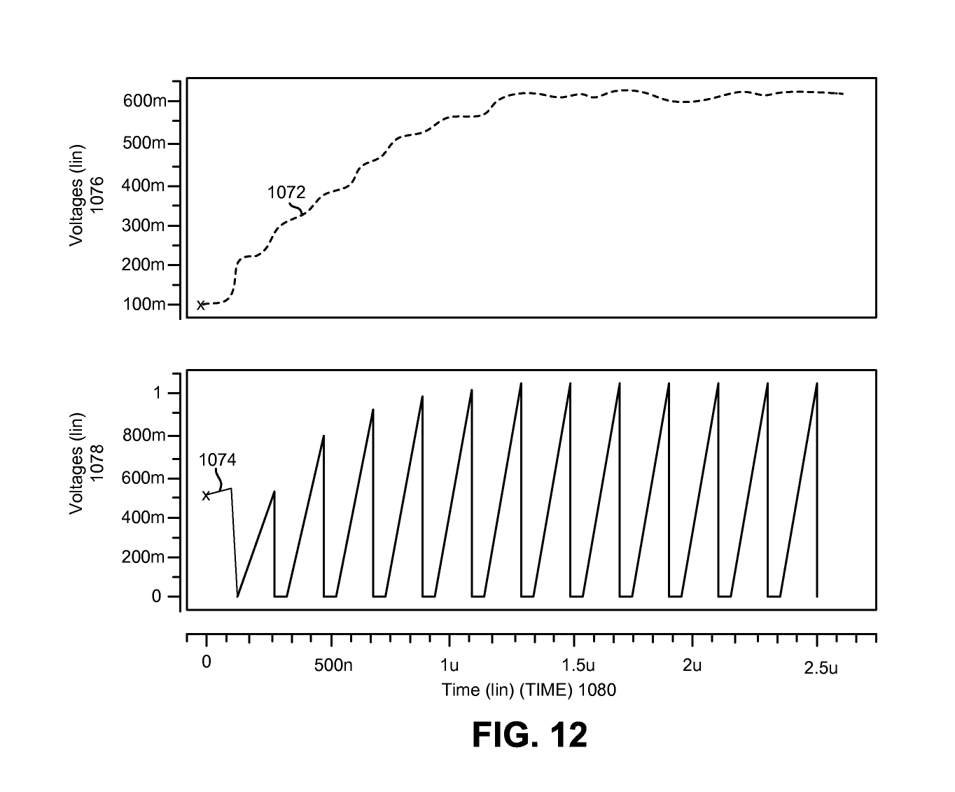

FIG. 12 is a graph illustrating the stabilization of a constant current source 696 with feedback. The output voltage 1076 of the constant current source 696, Vᵣₐₘₚ 1072, is shown over time 1080. The time 1080 scale of FIG. 12 shows microsecond values (e.g., 1u=1 microsecond). Vᵣₐₘₚ 1072 may increase to Vₘₐₓ (approximately 600 millivolts in the example of FIG. 12) over a period of time. For example, Vᵣₐₘₚ 1072 may approach Vₘₐₓ after 6-7 cycles. Vᵣₐₘₚ 1072 may approach linearity while maintaining the proper slope. The output voltage 1078 of the feedback circuit 552 feedback voltage node 1074 is also shown over time 1080. The feedback voltage node 1074 may switch between 0 volts and VDD (approximately one volt in the example of FIG. 12) to maintain the linearity and proper slope of Vᵣₐₘₚ 1072.

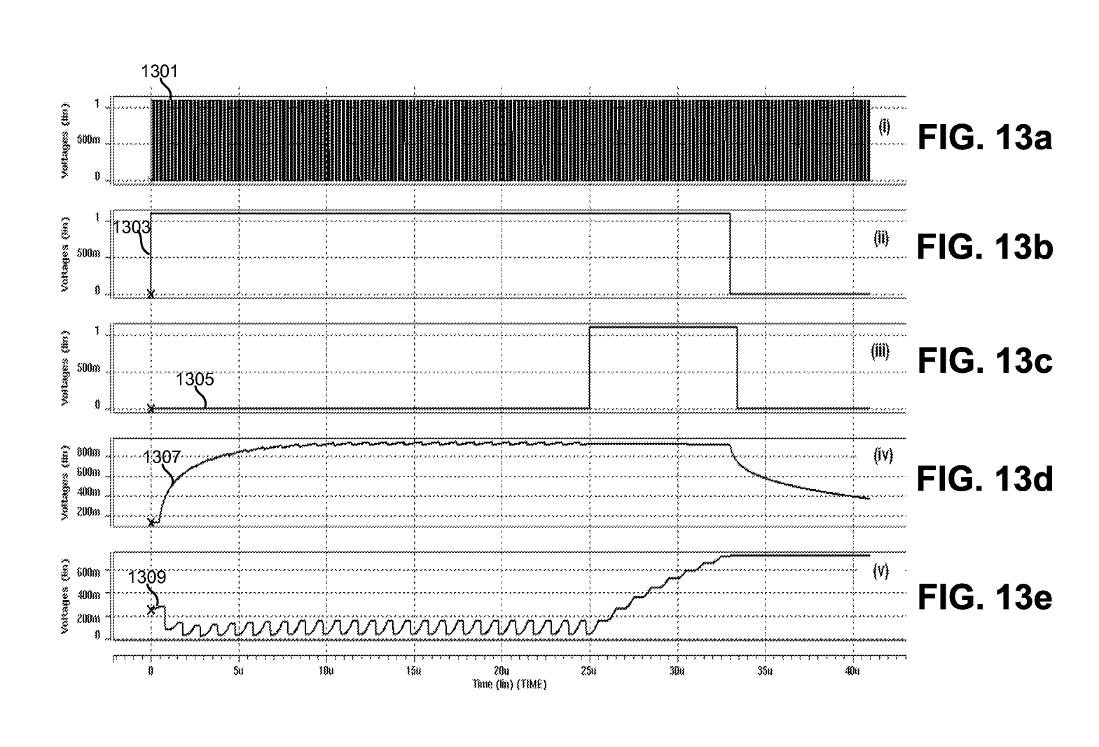

FIG. 13a-13e are graphs illustrating the various waveforms over time in a DUT 104 that is operated in test mode. FIG. 13a illustrates a waveform 1301 of the input frequency reference signal 424. FIG. 13b illustrates a waveform 1303 of the test mode enable signal 445. FIG. 13c illustrates a waveform 1305 of the capture signals that may be generated internally in the control module 554. FIG. 13d illustrates a waveform 1307 of the process-stabilized current drive bias voltage. FIG. 13e illustrates a waveform 1309 of the current source/LPF 550 output voltage.

The control voltage provided to the constant current source 548 may be adjusted using the feedback scheme as explained earlier. The calibration process may be observed in the waveform 1307 where a constant bias voltage is reached within the first 15 microseconds of the calibration process. The effective output ramp waveform 1309 produced by the current source may be observed from 0 to 25_S before the test enable signal 445 is applied (shown in the waveform 1305 in FIG. 13c). In test mode, the LPF 550 may be connected at the output of the constant current source 548 and may be controlled by the PFD 414 output as explained earlier. The effective integrated signal 1309 at the LPF 550 output at the end of test mode is latched at 30 microseconds and may be read out using the PPMU connected to the I/O pin 546. The voltage value of the integrated output signal 1309 at the end of the capture window may be observed at 35 microseconds in FIG. 13e. The measurement window duration τ may be set in such a way that the integrated PFD 414 signal should not reach the supply rail voltage value and saturate even for a relatively fast possible process corner. This may help identify marginal shorts that may not be screened with a conventional PLL 408 test but may cause reliability hazards as discussed in the fault coverage section.

Frequency independence may be an added value to any PLL 408 BIST scheme since a single SoC/SiP may contain either programmable PLLs 408 that run at multiple speeds or multiple PLLs 408 with different locking frequencies. Any BIST that uses at-speed signals from the feedback loop between VCO 420 and PFD 414 may need to be tuned for the operational frequency of the PLL 408 and is likely to be unusable for multiple frequencies. The present stimulus and observed PFD 414 output is baseband in nature, making it possible to program the scheme for multiple operating frequencies. VCO 420 output frequency is a direct function of the input reference voltage applied and by changing the pulse width of the ATE 102 stimulus applied, a different LFₒᵤₜ voltage may be programmed into the DUT 104. Design simulations may determine the CP 416 charging duration to be provided by the ATE 102 and thus the present systems and methods are completely frequency independent, i.e., usable with either multiple PLLs 408 of varying frequency or a programmable PLL 408 with a wide range of operating frequencies. Individual connections from the PDₒᵤₜ nodes in each of the blocks under test can be connected to the BIST controller 444 through a multiplexing scheme. Similarly, a multiplexer 446 that is activated in test mode for the specific block may be used to route the test stimulus to CPᵢₙ node.

If a system has a functional or mission mode operating frequency of fₒₚᵣ, it may be desirable to perform production testing at fₒₚᵣ to maintain test quality. Any mission mode testing performed at a frequency f₁ that is less than fₒₚᵣ may not assure desired at speed performance. Conventional PLL 408 testing involves feeding the PLL 408 output to an ATE 102 resource that then records the PLL 408 output signal. PLL 408 testing done on digital testers is typically limited to performing a PLL-lock test that tests for gross defects such as the ability of a PLL 408 to lock within the maximum allowed time specification.

Thus, an ATE 102 resource used for receiving (and processing) PLL 408 output may need to operate at-speed, (i.e., at the PLL 408 output frequency) to communicate with PLL 408 output. Multiple approaches are used in commercial ATE 102 systems. For example, some of the systems include per pin resources with high speed data reception on all pins while some of the lower cost ATE 102 systems designate certain resources that can handle high frequencies while a majority of the pin resources have a limited input frequency capability. Limiting the number of pin resources with high speed capability may complicate the DUT 104 docking board design since the specific high-speed channels/pins on the ATE 102 may need to be matched with corresponding DUT 104 resources. Further design complications and constraints may arise in case of economical multi-DUT 104 boards used in the industry.

The present systems and methods may use looped-self-testing for high speed nodes and modules and a DC baseband signal representing the self-test operation may be used for decision making This may eliminate any high-speed requirements from ATE 102 pins interfacing with the DUT 104. PPMU units are common on all ATE 102 channels/pins on the lowest resource ATE 102 since they are used in basic continuity measurements during production testing. The use of basic PPMU pins for BIST output measurement simplifies the ATE 102 measurement and decision making of the PLL 408 test. Thus, simple criteria as shown in equation (18), similar to typical pin continuity tests, may be used on the ATE. The upper and lower measurement limits may be determined by the process-split characterization work done during product bring-up phase:

if (lower-limit<Vₒᵤₜ[BIST]<upper-limit),

then_PASS,else_FAIL (18)

where lower-limit is the numerical lower bound set for a passing case of the BIST measurement while upper-limit is the numerical upper bound set for the passing case of the BIST measurement. Thus, low ATE 102 resources in measurement capabilities, memory and decision making may be required in the BIST scheme, in alignment with earlier stated goals.

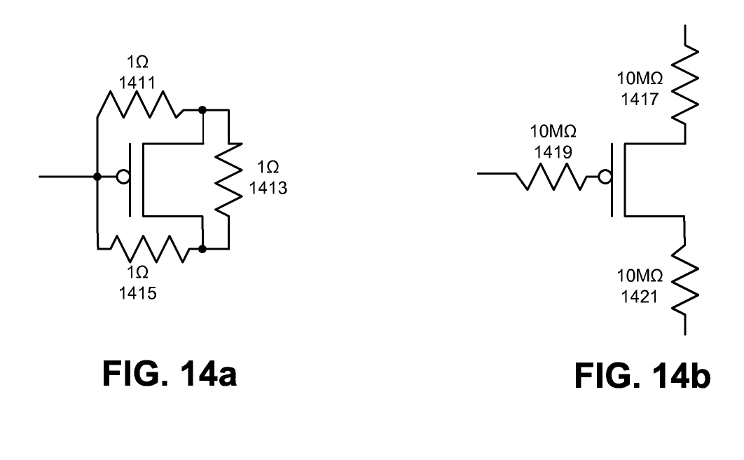

FIGS. 14a-b are circuit diagrams illustrating three transistor fault model conditions. The present systems and methods enable testing of catastrophic, marginal as well as parametric failures in the PLL 408. Some PLL 408 BISTs may consider fault coverage only for catastrophic failures in the internal digital and mixed signal blocks because parametric test capability may not exist for such schemes. Both types of fault coverage will be discussed, i.e., typical fault coverage and parametric fault coverage.

A closed-loop frequency latching test may be used in order to observe the fault coverage over the entire circuit. This basic test involves applying the CP 416 input in test mode using short data bursts, i.e., the PFD 414 output is integrated over a time interval [0; t″] and observed using the PPMU. Successively stable and consistent measurements on the LPF 550 may indicate the locked state of the PLL 408. This method is used in the BIST scheme to avoid using an ATE 102 frequency measurement resource on the PLL 408 output pin. The closed-loop frequency latching test may be described as: for t″≈T_{lock}/2+τ, if LOCKED, Mᵢ[0,t″]=Mⱼ[0,t″], else use equation (19):

Mᵢ[0,t″]≠Mⱼ[0,t″] (19)

where M is a matrix containing the finite output set for a variable ‘t’. A stuck-at fault model may be considered for the PFD 414 while a catastrophic fault model may be considered for the internal mixed signal blocks. Transistor level faults are modeled as transistor terminal shorts, with a 1Ω bridging resistance 1411, 1413, 1415 and contacts open with 10MΩ minimum resistance 1417, 1419, 1421 across ordinarily connected nodes. The fault models are represented in FIG. 14 with all three possible short/opens shown. Specifically, FIG. 14a illustrates a transistor with a 1Ω 1411 bridge between the gate and source, a 1Ω 1413 bridge between the source and drain, and a 1Ω 1415 bridge between the gate and drain. Similarly, FIG. 14b illustrates open circuits with 10MΩ resistances 1417, 1419, 1421 across the same connections.

In addition to typical fault model based coverage, the present PLL 408 BIST may test for parametric fault coverage. Parametric faults are likely to be caused by fabrication marginalities and the series/shunt path resistances may be between the ideal and the catastrophic values in FIG. 14.

Parametric fault coverage may be represented either in terms of passing range of the observed parameters (USL>PPMU_out>LSL) or statistically in the form of repeated convolutions to represent interdependency of the closed loop system. Due to the closed-loop nature of the individual blocks, the observed integrated PFD 414 output may be represented as a sum of convolutions of successive parameters as described in equation (20):

$$M [ {PD}_{out} ] = {\sum }_{m = min}^{m = max} {Module}_{i} [ m ] \cdot {Module}_{i + 1} [ n - m ] \qquad ( 20 )$$

for Moduleᵢ: i^{th} module in the closed loop.

Various specification based tests may be used for parametric testing, increasing overall fault coverage for marginalities and reliability hazards. Some faults, such as an open in one of the telescopic arms of the current mirror used in the CP 416 module, may still allow the VCO 420 to be driven to a level where the PLL 408 can be locked. The remaining functional branches may carry additional or uneven current causing electromigration risk during field use of the DUT 104. This fault may be difficult to screen during a typical lock test but an intermediate value of the PDₒᵤₜ may be characterized on various process corners to identify such moderate low-slope charging devices. Similar characterization can be performed on the measured node to screen out marginal short connections.

Conventional PLL 408 testing in production is limited to testing the PLL 408 locking mechanism and passing the DUT 104 if the PLL 408 locks to the input frequency within t_{lock}. A gross fabrication fault in the PLL 408 would disable the DUT 104 from frequency-locking while a fabrication marginality may cause an abnormality in the lock time. Most of the PLL 408 tests are directed at ensuring t_{lock}<tₗᵢₘᵢₜ as a rejection criterion while typically no test targets a lower limit on t_{lock}. A fabrication marginality causing voids/metal trace narrowing may increase the locking time and would be caught but a via overfill or any marginal short that causes a high current flow is likely to cause higher than nominal drive current through the charge pump, causing a frequency lock in a shorter than nominal interval. Such a marginal short is likely to escape a PLL 408 lock test, and DUT 104 level quiescent current testing may not screen this part out since the leakage current may be a fraction of the overall quiescent current. A marginal short is likely to cause reliability issues in the DUT 104 on continued operation as the excessive current drawn through the leakage path is likely to cause electromigration, resulting in an electrical open at later stages of its operating life.

Parametric testing may provide a screen for such marginal parts since their manifestation into internal parameters is more likely to be detected than the overall system output. A closed loop system may be able to compensate for such marginalities, effectively masking the faults during testing. Driving an input signal at an internal node during test mode and observing the corresponding driver node in an ‘opened-close-loop’ system may provide the ability to perform numerical limit based testing for the internal parameter observed.

Depending on the quality matrices defined for the DUT 104, the following type of tests, described in equation (21), can be performed on the internal node. Furthermore, accessibility to the charging as well as discharging mechanism during the test mode enhances the testability as discussed earlier.

USL>∫₀^{t′}PDₒᵤₜ>LSL (21)

where: USL: Upper Spec Limit=Nominal Measurement+Guard-Band (GB); and LSL: Lower Spec Limit=Nominal Measurement+GB. USL and LSL may be used to compare the integrated PD output values against the established specification limits for making a pass/fail decision.

Similar CP discharge discharge testing, described in equation (22), may be performed for a specific time interval stimulus provided in the test mode to test the parametric limits in terms of charging as well as discharging. Equation (22) describes a discharge test that may be performed in order to characterize the voltage discharged for a specific test duration in terms of upper and lower specification limits characterized for the DUT.

USL₂>∫ₜ₂^{t1}PDₒᵤₜ>LSI₂ (22)

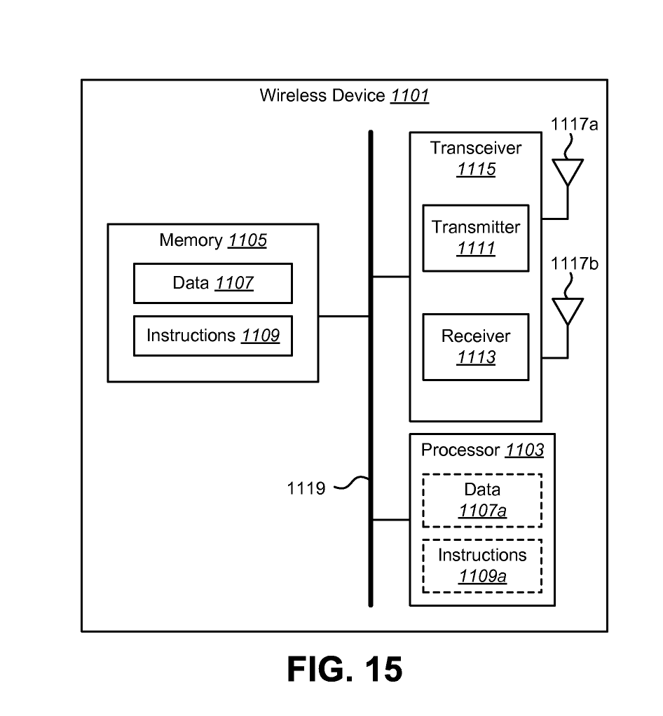

FIG. 15 illustrates certain components that may be included within a wireless device 1101. The wireless device 1101 may be a mobile device/station or a base station. Examples of mobile stations include cellular phones, handheld wireless devices, wireless modems, laptop computers, personal computers, etc. A mobile station may alternatively be referred to as an access terminal, a mobile terminal, a subscriber station, a remote station, a user terminal, a terminal, a subscriber unit, user equipment, etc. The present systems and methods may be used on an integrated circuit 106 that may be part of a wireless device 1101. Additionally, the present systems and methods may be used on an integrated circuit 106 that may be an electronic device that is not a wireless device 1101. However, the electronic device block diagram and components would be similar to the wireless device 1101 of FIG. 15 except that the electronic device may not have a transceiver 1115.

The wireless device 1101 includes a processor 1103. The processor 1103 may be a general purpose single- or multi-chip microprocessor (e.g., an ARM), a special purpose microprocessor (e.g., a digital signal processor (DSP)), a microcontroller, a programmable gate array, etc. The processor 1103 may be referred to as a central processing unit (CPU). Although just a single processor 1103 is shown in the wireless device 1101 of FIG. 15, in an alternative configuration, a combination of processors (e.g., an ARM and DSP) could be used.

The wireless device 1101 also includes memory 1105. The memory 1105 may be any electronic component capable of storing electronic information. The memory 1105 may be embodied as random access memory (RAM), read only memory (ROM), magnetic disk storage media, optical storage media, flash memory devices in RAM, on-board memory included with the processor, EPROM memory, EEPROM memory, registers, and so forth, including combinations thereof.

Data 1107 and instructions 1109 may be stored in the memory 1105. The instructions 1109 may be executable by the processor 1103 to implement the methods disclosed herein. Executing the instructions 1109 may involve the use of the data 1107 that is stored in the memory 1105. When the processor 1103 executes the instructions 1107, various portions of the instructions 1109a may be loaded onto the processor 1103, and various pieces of data 1107a may be loaded onto the processor 1103.

The wireless device 1101 may also include a transmitter 1111 and a receiver 1113 to allow transmission and reception of signals to and from the wireless device 1101. The transmitter 1111 and receiver 1113 may be collectively referred to as a transceiver 1115. An antenna 1117 may be electrically coupled to the transceiver 1115. The wireless device 1101 may also include (not shown) multiple transmitters, multiple receivers, multiple transceivers and/or multiple antenna (e.g., 1117a, 1117b).

The various components of the wireless device 1101 may be coupled together by one or more buses, which may include a power bus, a control signal bus, a status signal bus, a data bus, etc. For the sake of clarity, the various buses are illustrated in FIG. 15 as a bus system 1119.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “processor” should be interpreted broadly to encompass a general purpose processor, a central processing unit (CPU), a microprocessor, a digital signal processor (DSP), a controller, a microcontroller, a state machine, and so forth. Under some circumstances, a “processor” may refer to an application specific integrated circuit (ASIC), a programmable logic device (PLD), a field programmable gate array (FPGA), etc. The term “processor” may refer to a combination of processing devices, e.g., a combination of a DSP and a microprocessor, a plurality of microprocessors, one or more microprocessors in conjunction with a DSP core, or any other such configuration.

The term “memory” should be interpreted broadly to encompass any electronic component capable of storing electronic information. The term memory may refer to various types of processor-readable media such as random access memory (RAM), read-only memory (ROM), non-volatile random access memory (NVRAM), programmable read-only memory (PROM), erasable programmable read only memory (EPROM), electrically erasable PROM (EEPROM), flash memory, magnetic or optical data storage, registers, etc. Memory is said to be in electronic communication with a processor if the processor can read information from and/or write information to the memory. Memory that is integral to a processor is in electronic communication with the processor.

The terms “instructions” and “code” should be interpreted broadly to include any type of computer-readable statement(s). For example, the terms “instructions” and “code” may refer to one or more programs, routines, sub-routines, functions, procedures, etc. “Instructions” and “code” may comprise a single computer-readable statement or many computer-readable statements.

The functions described herein may be implemented in hardware, software, firmware, or any combination thereof. If implemented in software, the functions may be stored as one or more instructions on a computer-readable medium. The terms “computer-readable medium” or “computer-program product” refers to any available medium that can be accessed by a computer. By way of example, and not limitation, a computer-readable medium may comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIGS. 7 and 8 can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a device may obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An integrated circuit configured for a phase locked loop (PLL) built in self test (BIST), comprising:
a phase detector, wherein the phase detector produces a digital signal that describes a comparison between a reference signal and a feedback signal;
a BIST controller, wherein the BIST controller accumulates the digital signal with successive digital signals; and
a communication pin, wherein the communication pin provides the accumulated signal for automatic test equipment (ATE) to determine whether the PLL is operating correctly based on the accumulated signal.

2. The integrated circuit of claim 1, further comprising a constant current source, wherein the constant current source drives a low pass filter without affecting the operating characteristics of the phase locked loop (PLL).

3. The integrated circuit of claim 2, further comprising:
feedback circuitry for the constant current source, wherein the feedback circuitry provides a ramp slope for the constant current source;
a calibration controller, wherein the calibration controller provides control signals to the constant current source for process-independent calibration; and
a hold circuit, wherein the hold circuit provides a set bias voltage to the constant current source once calibration is complete.

4. The integrated circuit of claim 3, wherein the feedback circuitry comprises a clocked comparator.

5. The integrated circuit of claim 1, further comprising an N-divider that provides the feedback signal to the phase detector.

6. The integrated circuit of claim 5, further comprising a voltage controlled oscillator coupled to the N-divider.

7. The integrated circuit of claim 1, wherein the built in self test (BIST) controller uses a low pass filter (LPF) to accumulate the digital signal with successive digital signals.

8. The integrated circuit of claim 1, further comprising a multiplexer that connects a charge pump to the phase detector during a mission mode, and connects the charge pump to the built in self test (BIST) controller during test mode.

9. The integrated circuit of claim 1, wherein the phase detector includes a frequency detector.

10. A method for a phase locked loop (PLL) built in self test (BIST), comprising:
producing a digital signal that describes a comparison between a reference signal and a feedback signal;
sending the digital signal through the PLL;
accumulating the digital signal with successive digital signals; and
determining whether the PLL is operating correctly based on the accumulated signal.

11. The method of claim 10, wherein the accumulating does not affect the operating characteristics of the phase locked loop (PLL).

12. The method of claim 11, further comprising:
generating a constant current with a constant current source;
providing feedback to the constant current source;
providing control signals to the constant current source for process-independent calibration; and
providing a set bias voltage to the constant current source once calibration is complete.

13. The method of claim 12, wherein the providing feedback comprises using a clocked comparator.

14. The method of claim 10, wherein the determining whether the phase locked loop (PLL) is operating correctly comprises comparing the accumulated signal to simulated data.

15. The method of claim 14, wherein the simulated data is a simulated signature of an output of a phase detector during phase locked loop (PLL) start up.

16. The method of claim 10, wherein the accumulating comprises using a low pass filter (LPF) to accumulate the digital signal with successive digital signals.

17. The method of claim 10, further comprising connecting a charge pump to a phase detector during a mission mode, and connecting the charge pump to a built in self test (BIST) controller during test mode.

18. An apparatus for performing a phase locked loop (PLL) built in self test (BIST), the apparatus comprising:
a phase detector, wherein the phase detector is configured to produce a digital signal that describes a comparison between a reference signal and a feedback signal;
a BIST controller, wherein the BIST controller is configured to accumulate the digital signal with successive digital signals; and
a communication pin, wherein the communication pin provides the accumulated signal for automatic test equipment (ATE) to determine whether the PLL is operating correctly based on the accumulated signal.

19. The apparatus of claim 18, further comprising a constant current source, wherein the constant current source is configured to drive a low pass filter without affecting the operating characteristics of the phase locked loop (PLL).

20. The apparatus of claim 19, further comprising:
feedback circuitry for the constant current source, wherein the feedback circuitry is configured to provide a ramp slope for the constant current source;
a calibration controller, wherein the calibration controller is configured to provide control signals to the constant current source for process-independent calibration; and
a hold circuit, wherein the hold circuit is configured to provide a set bias voltage to the constant current source once calibration is complete.

21. The apparatus of claim 20, wherein the feedback circuitry comprises a clocked comparator.

22. The apparatus of claim 18, further comprising an N-divider that provides the feedback signal to the phase detector.

23. The apparatus of claim 22, further comprising a voltage controlled oscillator coupled to the N-divider.

24. The apparatus of claim 18, wherein the built in self test (BIST) controller uses a low pass filter (LPF) to accumulate the digital signal with successive digital signals.

25. The apparatus of claim 18, further comprising a multiplexer that is configured to connect a charge pump to the phase detector during a mission mode, and connects the charge pump to the built in self test (BIST) controller during test mode.

26. The apparatus of claim 18, wherein the phase detector includes a frequency detector.

27. An apparatus for performing a phase locked loop (PLL) built in self test (BIST), the apparatus comprising:
means for producing a digital signal that describes a comparison between a reference signal and a feedback signal;
means for sending the digital signal through the PLL;
means for accumulating the digital signal with successive digital signals; and
means for determining whether the PLL is operating correctly based on the accumulated signal.

28. The apparatus of claim 27, the means for accumulating does not affect the operating characteristics of the phase locked loop (PLL).

29. The apparatus of claim 27, wherein the means for determining whether the phase locked loop (PLL) is operating correctly comprises means for comparing the accumulated signal to simulated data.

30. The apparatus of claim 29, wherein the simulated data comprises a simulated signature of an output of a phase detector during phase locked loop (PLL) start up.
